(19) United States
(12) Patent Application Publication
(10) Pub. No.: US 2023/0337743 A1
(43) Pub. Date: Oct. 26, 2023

(54) ELECTRONIC VAPORIZATION DEVICE, VAPORIZER, VAPORIZATION CORE, AND PREPARATION METHOD THEREFOR

(71) Applicant: SHENZHEN SMOORE TECHNOLOGY LIMITED, Shenzhen (CN)

(72) Inventors: Hongxia LV, Shenzhen (CN); Pei LI, Shenzhen (CN); Zhenlong JIANG, Shenzhen (CN)

(21) Appl. No.: 18/302,250

(22) Filed: Apr. 18, 2023

(30) Foreign Application Priority Data
Apr. 20, 2022 (CN) 202210418908.9

(51) Int. Cl. A24F 40/46; A24F 40/10; A24F 40/70; C23C 14/34; C23C 14/14; C23C 14/04; C23C 14/58; H05B 3/18

(52) U.S. Cl. CPC A24F 40/46; A24F 40/10; A24F 40/70; C23C 14/34; C23C 14/14; C23C 14/042; C23C 14/5806; C23C 14/5853; H05B 3/18; H05B 2203/016; H05B 2203/021

(57) ABSTRACT

A vaporization core includes: a porous substrate having a vaporization surface; a heating layer disposed on the vaporization surface of the porous substrate; and a protective layer disposed on a surface of the heating layer far away from the porous substrate. The protective layer includes metal aluminum and alumina, and the alumina at least partially covers a surface of the metal aluminum to form an alumina layer.

### CROSS-REFERENCE TO PRIOR APPLICATION

Priority is claimed to Chinese Patent Application No. 202210418908.9, filed on Apr. 20, 2022, the entire disclosure of which is hereby incorporated by reference herein.

### FIELD

This application relates to the field of vaporizer technologies, and in particular, to an electronic vaporization device, a vaporizer, a vaporization core, and a preparation method therefor.

### BACKGROUND

An electronic vaporization device generally includes a vaporizer and a power supply component. The power supply component is configured to supply power to the vaporizer. The vaporizer heats and vaporizes an aerosol-forming medium in the powered-on state, so as to be absorbed by a user. A vaporization core includes a porous substrate and a heating element. In a heating and vaporization process of the vaporizer, mainly the heating element of the vaporization core heats in the powered-on state, so as to heat and vaporize the aerosol-forming medium.

Generally, the heating element of the vaporization core is a metal heating film layer. However, in the process of vaporization, the heating element of the vaporization core is easily oxidized and fails when e-liquid supply is insufficient, which affects product stability and service life.

### SUMMARY

In an embodiment, the present invention provides a vaporization core, comprising: a porous substrate having a vaporization surface; a heating layer disposed on the vaporization surface of the porous substrate; and a protective layer disposed on a surface of the heating layer far away from the porous substrate, wherein the protective layer comprises metal aluminum and alumina, and the alumina at least partially covers a surface of the metal aluminum to form an alumina layer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic structural diagram of an electronic vaporization device according to this application;

FIG. 2 is a schematic structural diagram of a vaporizer in the electronic vaporization device according to FIG. 1;

FIG. 3 is a schematic structural diagram of a first embodiment of a vaporization core in FIG. 2;

FIG. 4 is a schematic structural diagram of a top view of the vaporization core in FIG. 3;

FIG. 5 is a schematic structural diagram of a second embodiment of a vaporization core in FIG. 2;

FIG. 6 is a schematic structural diagram of another implementation of the vaporization core in FIG. 5;

FIG. 7 is a schematic structural diagram of still another implementation of the vaporization core in FIG. 5;

FIG. 8 is a schematic flowchart of an embodiment of a vaporization core preparation method according to this application;

FIG. 9 is a schematic structural diagram of a surface of step S3 in the vaporization core preparation method according to FIG. 8;

FIG. 10 is a schematic flowchart of another embodiment of a vaporization core preparation method according to this application; and

FIG. 11 is a schematic structural diagram of a surface of step S4 in the vaporization core preparation method according to FIG. 10.

### DETAILED DESCRIPTION

In an embodiment, the present invention provides an electronic vaporization device, a vaporizer, a vaporization core, and a preparation method therefor, so as to resolve the technical problem in the prior art that a metal heating film layer on a vaporization core is prone to failure and has short service life in the vaporization process.

In an embodiment, the present invention provides a vaporization core, and the vaporization core includes a porous substrate, a heating layer, and a protective layer. The porous substrate has a vaporization surface; the heating layer is disposed on the vaporization surface of the porous substrate; and the protective layer is disposed on the surface of the heating layer far away from the porous substrate; where the protective layer includes metal aluminum and alumina, and the alumina at least partially covers the surface of the metal aluminum to form an alumina layer.

The metal aluminum includes an aluminum film layer and/or an aluminum particle form.

The alumina is filled between adjacent aluminum particles, and multiple aluminum particles and the alumina are in contact with the heating layer.

The alumina completely covers the surfaces of multiple aluminum particles not in contact with the heating layer.

The vaporization core further includes two electrodes, the electrodes are disposed on the surface of the heating layer far from the porous substrate, and the protective layer and the two electrodes jointly cover the heating layer.

The thickness of the alumina layer is 100 nm to 600 nm; and/or the particle diameter of the aluminum particle is 100 nm to 3 μm; and/or

the thickness of the aluminum film layer is 100 nm to 1 μm.

In order to resolve the foregoing technical problem, this application adopts the second technical solution that is as follows: A vaporizer is provided, the vaporizer includes a liquid storage cavity configured to store an aerosol-forming medium and any vaporization core described above, and the vaporization core is configured to heat and vaporize the aerosol-forming medium.

In order to resolve the foregoing technical problem, this application adopts the third technical solution that is as follows: An electronic vaporization device is provided, the electronic vaporization device includes a power supply component and the vaporizer described above, and the power supply component is configured to provide energy for the vaporizer.

In order to resolve the foregoing technical problem, this application adopts the fourth technical solution that is as follows: A vaporization core preparation method is provided, including: obtaining a porous substrate on which a heating layer is deposited; depositing metal aluminum on the surface of the heating layer far away from the porous substrate; and oxidizing the metal aluminum.

The step of depositing metal aluminum on the surface of the heating layer far away from the porous substrate specifically includes: depositing metal aluminum with a thickness of 100 nm to 1 μm on the surface of the heating layer far away from the porous substrate.

The step of oxidizing the metal aluminum specifically includes:

oxidizing the metal aluminum for 50 min to 70 min at the air atmosphere and a temperature of 400° C. to 700° C.

The vaporization core preparation method further includes: annealing the oxidized metal aluminum. The step of annealing the oxidized metal aluminum specifically includes:

annealing the oxidized metal aluminum for 6 h to 24 h at a vacuum degree of 0.01 Pa to 100 Pa and a temperature of 650° C. to 900° C.

Beneficial effects of this application are as follows: Different from the prior art, this application discloses an electronic vaporization device, a vaporizer, a vaporization core, and a preparation method therefor. The vaporization core includes a porous substrate, a heating layer, and a protective layer; the porous substrate has a vaporization surface, the heating layer is disposed on the vaporization surface of the porous substrate, the protective layer is disposed on the surface of the heating layer far away from the porous substrate, the protective layer includes metal aluminum and alumina, and the alumina at least partially covers the surface of the metal aluminum to form an alumina layer. The protective layer is disposed on the surface of the heating layer far away from the porous substrate. In the heating and vaporization process, the protective layer protects the heating layer, so as to avoid that the heating layer fails due to oxidation in the vaporization process, thereby improving stability of the heating layer, and further increasing the service life of the heating layer.

The technical solutions in embodiments of this application are clearly and completely described in the following with reference to the accompanying drawings in the embodiments of this application. Apparently, the described embodiments are merely some rather than all of the embodiments of this application. All other embodiments obtained by a person of ordinary skill in the art based on the embodiments of this application without creative efforts shall fall within the protection scope of this application.

The terms “first”, “second”, and “third” in the embodiments of this application are merely intended for a purpose of description, and shall not be understood as an indication or implication of relative importance or implicit indication of the number of indicated technical features. Therefore, features defining “first”, “second”, and “third” can explicitly or implicitly include at least one feature. In description of this application, “multiple” means at least two, such as two and three unless it is specifically defined otherwise. In addition, the terms “include”, “have”, and any variant thereof are intended to cover a non-exclusive inclusion. For example, a process, method, system, product, or device that includes a series of steps or units is not limited to the listed steps or units; and instead, further optionally includes a step or unit that is not listed, or further optionally includes another step or unit that is intrinsic to the process, method, product, or device.

Embodiment mentioned in the specification means that particular features, structures, or characteristics described with reference to the embodiment may be included in at least one embodiment of this application. The term appearing at different positions of this specification may not refer to the same embodiment or an independent or alternative embodiment that is mutually exclusive with another embodiment. A person skilled in the art explicitly or implicitly understands that the embodiments described in the specification may be combined with other embodiments.

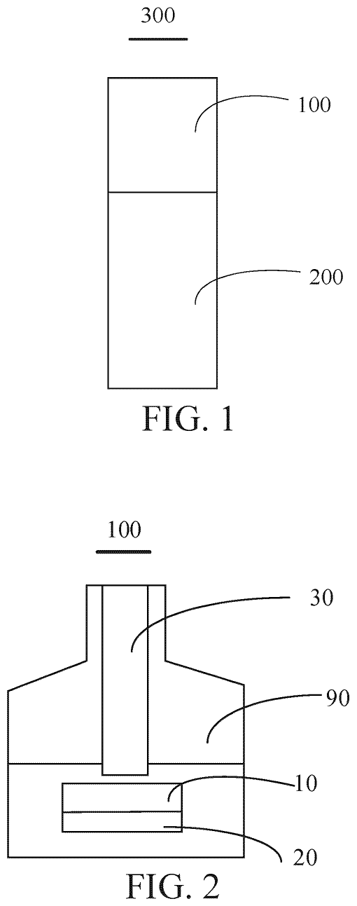

Referring to FIG. 1 and FIG. 2, FIG. 1 is a schematic structural diagram of an electronic vaporization device according to this application. FIG. 2 is a schematic structural diagram of a vaporizer in the electronic vaporization device according to FIG. 1.

Referring to FIG. 1, this application provides an electronic vaporization device 300. The electronic vaporization device 300 includes a vaporizer 100 and a power supply component 200. The power supply component 200 is configured to provide energy for the vaporizer 100. The vaporizer 100 is configured to heat and vaporize an aerosol-forming medium in the powered-on state, so as to generate an aerosol to be absorbed by a user.

Optionally, the vaporizer 100 and the power supply component 200 in the electronic vaporization device 300 may be of an integral structure, or may be removably connected, and may be designed according to a specific requirement.

As shown in FIG. 2, the vaporizer 100 includes a liquid storage cavity 90, an air outlet pipe 30, a vaporization core 10, and a vaporization cavity 20 formed in the vaporizer 100. The liquid storage cavity 90 is configured to store an aerosol-forming medium, the vaporization core 10 is configured to absorb the aerosol-forming medium in the liquid storage cavity 90, and heat and vaporize the absorbed aerosol-forming medium to finally form an aerosol. The aerosol generated by the vaporization is in the vaporization cavity 20, and the aerosol flows through the air outlet pipe 30 with the external air and finally flows out of the vaporizer 100.

A heating element of the vaporization core is usually a metal heating film layer. The nano particles of the metal heating film layer are susceptible to oxidation and fail during sintering and vaporization, especially when e-liquid supply is insufficient. In the prior art, a protective layer formed of precious metal such as gold and platinum is generally disposed on the surface of the metal heating film layer to resolve the technical problems of easy oxidation and failure of the metal heating film layer. However, particles such as gold and platinum are prone to over-burning when there is less aerosol-forming medium, which causes agglomeration of precious metal particles, and causes the metal heating film layer to be exposed to air and be oxidate and fail. In addition, the precious metal protective layer has relatively high costs. In view of this, this application provides a vaporization core 10, which is specifically described as follows.

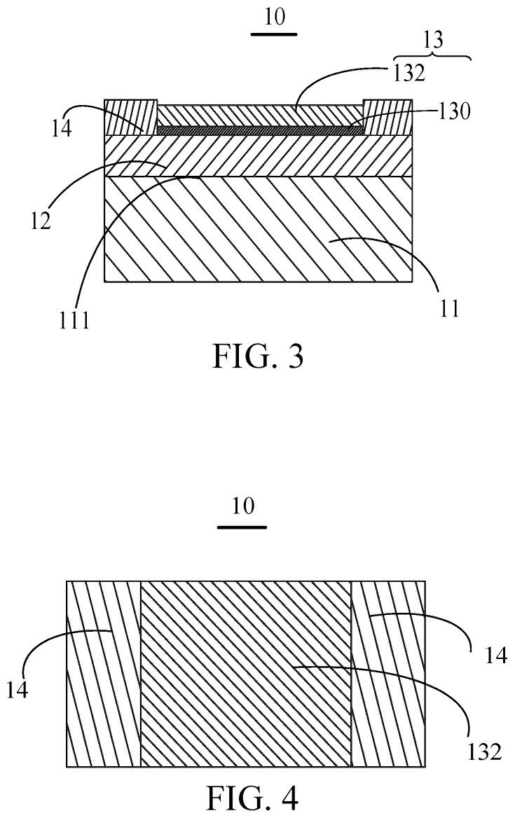

Referring to FIG. 3 and FIG. 4, FIG. 3 is a schematic structural diagram of a first embodiment of the vaporization core in FIG. 2, and FIG. 4 is a schematic structural diagram of a top view of the vaporization core in FIG. 3.

The vaporization core 10 includes a porous substrate 11, a heating layer 12, and a protective layer 13, where the porous substrate 11 has a vaporization surface 111, the heating layer 12 is disposed on the vaporization surface 111 of the porous substrate 11, and the protective layer 13 is disposed on the surface of the side of the heating layer 12 far away from the porous substrate 11 and covers the heating layer 12. The protective layer 13 includes metal aluminum and alumina, and the alumina at least partially covers the surface of the metal aluminum to form an alumina layer 132. The protective layer 13 is disposed on the surface of the side of the heating layer 12 far away from the porous substrate 11, so that oxidation of the heating layer 12 in direct contact with air in the vaporization process and oxidation of the heating layer 12 in the sintering process of the electrode 14 can be avoided, which causes the problem that the heating layer 12 fails. This resolves the problem in the prior art that the metal heating film layer is easily oxidized and fails in the sintering and vaporization process of the electrode, and also resolves the problem in the prior art that when a precious metal material is used as the protective layer, and the aerosol-forming medium is insufficient, precious metal particles are prone to over-burning and agglomeration and cause the failure of the vaporization core. This helps improve stability of the vaporization core 10 and prolong the service life of the vaporization core 10.

Referring to FIG. 3, in this embodiment, the protective layer 13 is disposed on the surface of the heating layer 12 far away from the porous substrate 11, and the protective layer 13 includes metal aluminum and alumina, where the metal aluminum is an aluminum film layer 130, and the aluminum film layer 130 is a continuous porous structure or a mesh structure. The alumina covers the surface of metal aluminum to form the alumina layer 132. The alumina layer 132 is located on the surface of the side of the aluminum film layer 130 far away from the porous substrate 11. The alumina layer 132 is relatively stable, chemically stable, has relatively high melting point and boiling point, and has relatively strong high temperature resistance performance. In the vaporization process, even when the aerosol-forming medium in the vaporization core 10 is insufficient and over-burning occurs, particle agglomeration due to over-burning does not occur in the protective layer 13, which causes the problem of failure of the vaporization core 10. This effectively resolves the foregoing problems in the prior art. In addition, compared with the prior art in which precious metal materials such as gold and platinum are used to prepare the protective layer 13, metal aluminum and alumina are used as materials of the protective layer 13, preparation costs of the protective layer 13 are lower, and preparation costs of the vaporizer 100 are effectively reduced.

Specifically, the protective layer 13 is formed after the metal aluminum deposited on the surface of the heating layer 12 is oxidized, and the oxidized part of the deposited metal aluminum forms the alumina layer 132, and the unoxidized part thereof forms the aluminum film layer 130. The thickness of the alumina layer 132 is in a range of 100 nm to 600 nm, preferably 100 nm to 300 nm, and more preferably 180 nm to 220 nm. In this embodiment, the thickness of the alumina layer 132 is 200 nm. It may be understood that, if the thickness of the alumina layer 132 is too small, structural strength of the alumina layer 132 is also lower, and stability of the vaporization core 10 is easily reduced. In addition, a barrier capability of the alumina layer 132 to the air or aerosol is also reduced, that is, protection performance of the alumina layer 132 to the heating layer 12 is weakened, and there is a risk that air contacts the heating layer 12, which causes oxidation failure of the heating layer 12, thereby affecting stability and service life of the vaporization core 10. If the thickness of the alumina layer 132 is too large, overall resistance of the vaporization core 10 is greatly reduced, thereby affecting heating efficiency of the vaporization core 10. The thickness of the aluminum film layer 130 is 100 nm to 1 μm, and the thickness of the aluminum film layer 130 is related to the oxidation degree, and is negatively related to the thickness of the formed alumina layer 132. That is, the thicker the alumina layer 132, the thinner the aluminum film layer 130.

The shape and the size of the porous substrate 11 are not limited. The porous substrate 11 is made of a material of a porous structure, for example, the porous substrate 11 may be made of porous ceramic, porous glass, porous plastic, or porous metal. In this embodiment, the material of the porous substrate 11 is a porous ceramic substrate. The porous ceramic has pores, and has functions of liquid guiding and liquid storage, so that the aerosol-forming medium in the liquid storage cavity 90 is absorbed by the porous substrate 11 and penetrates onto the vaporization surface 111 for heating and vaporization. In addition, the porous ceramic has a stable chemical property, and does not react with the aerosol-forming medium, and the porous ceramic is resistant to high temperature, and does not deform due to excessive heating temperature during vaporization. The porous ceramic is an insulator, and is not electrically connected to the heating layer 12 on the surface of the porous ceramic, a short circuit causing failure of the vaporization core 10 will not occur, and the porous ceramic is manufactured conveniently and costs thereof are low. In this embodiment, the porous substrate 11 is a rectangular porous ceramic.

In some embodiments, the porosity of the porous ceramic may be 30% to 70%. The porosity is the ratio of the total volume of small voids in a porous medium to the total volume of the porous medium. The porosity may be adjusted according to the composition of the aerosol-forming medium. For example, when the aerosol-forming medium has a relatively high viscosity, a relatively high porosity is selected to ensure the liquid guiding effect.

In some other embodiments, the porosity of the porous ceramic may be 50% to 60%. The porosity of the porous ceramic is 50% to 60%. On the one hand, it can be ensured that the porous ceramic has better liquid guiding efficiency, so as to prevent the phenomenon that the aerosol-forming medium does not flow smoothly and dry burning occurs, thereby improving the vaporization effect of the vaporizer 100. On the other hand, it can be avoided that the porosity of the porous ceramic is excessively high, liquid guiding is excessively fast, and it is difficult to lock the liquid. As a result, the probability of leakage increases greatly, and performance of the vaporizer 100 is affected.

In another embodiment, when the porous substrate 11 is fabricated by using another porous structure material, for a setting such as the porosity of the porous substrate 11, references may be made to a setting form on the porous ceramic. Details are not described herein again.

It may be understood that when the porous substrate 11 is porous glass, porous plastic, or porous metal, the porous glass, the porous plastic, or the porous metal may be formed by opening holes in a compact glass substrate, plastic substrate, or metal substrate.

When the porous substrate 11 is porous metal, an insulating layer is disposed between the porous substrate 11 and the heating layer 12, and the insulating layer is configured to insulate the porous substrate 11 from the heating layer 12, so as to avoid a short circuit caused when the porous substrate 11 and the heating layer 12 are electrically connected.

The heating layer 12 is disposed on the vaporization surface 111 of the porous substrate 11, and is heated in the powered-on state to heat and vaporize the aerosol-forming medium. Optionally, the heating layer 12 may be at least one of a heating film, a heating coating, a heating line, a heating plate, or a heating mesh. In this embodiment, the heating layer 12 is a porous heating film structure. It may be understood that the porous structure on the heating layer 12 may enable a liquid aerosol-forming medium to penetrate more efficiently to the surface of the heating layer 12 or the vaporization surface 111, thereby improving liquid guiding and heat conducting efficiency of the heating layer 12, and improving the vaporization effect of the vaporization core 10.

A material that can be stably bound to the porous substrate 11 may be selected as the material of the heating layer 12. For example, the heating layer 12 may be made of a material such as titanium, zirconium, titanium aluminum alloy, titanium zirconium alloy, titanium molybdenum alloy, titanium niobium alloy, iron aluminum alloy or tantalum aluminum alloy, or stainless steel.

Titanium and zirconium have the following features: Titanium and zirconium are biocompatible metal, especially titanium is also a biophilic metal element with higher safety. Titanium and zirconium have a relatively large resistivity in a metal material. In the normal temperature state, alloying thereof at a certain ratio has a resistivity three times the original resistivity, and is more suitable for a material that becomes the heating layer 12. Titanium and zirconium have a small thermal expansion coefficient, have a lower thermal expansion coefficient after alloying, and better match with porous ceramics. After alloying at a certain ratio, the melting point of the alloy is lower and the magnetron sputtering coating is better. After metal coating, it can be seen by electron microscope analysis that the microparticles thereof are spherical, and the microparticles coalesce to form a micromorphology similar to cauliflower. It can be seen by electron microscope analysis that the microparticles of the film formed by the titanium zirconium alloy are flake-like, a part of grain boundaries between the particles disappear, and continuity is better. Both titanium and zirconium have good plasticity and elongation, and titanium zirconium alloy films have better thermal cycle and current impact capability. Titanium is often used in a stress buffer layer of metal and ceramic, and used as an activated element for ceramic metallization. Titanium reacts with a ceramic interface to form a relatively strong chemical bond, thereby improving adhesion of the film. Based on the foregoing features of titanium and zirconium, in this embodiment, the heating layer 12 may be made of a titanium zirconium alloy material.

The thickness of the heating layer 12 is 0.1 μm to 10 μm. Specifically, the thickness of the heating layer 12 may be any specific thickness value of 0.1 μm, 1 μm, 2 μm, 3 μm, 4 μm, 5 μm, 6 μm, 7 μm, 8 μm, 9 μm, or 10 μm. Preferably, the thickness of the heating layer 12 is 2 μm to 5 μm. This thickness can ensure that the thickness of the heating layer 12 matches the pore diameter of the porous substrate 11, prevent the heating layer 12 from blocking a micro-pore that is in the porous substrate 11 and that is used for liquid guiding and liquid storage, improve liquid supply stability in the vaporization process of the vaporization core 10, and increase the service life thereof.

Optionally, the heating layer 12 may be prepared on the vaporization surface 111 of the porous substrate 11 by using a process such as physical vapor deposition or chemical vapor deposition. For example, the heating layer 12 may be prepared by using a process such as sputtering, evaporation coating, or atomic layer deposition. In this embodiment, the heating layer 12 is formed by means of sputtering.

In this embodiment, a titanium zirconium alloy film formed by using a titanium zirconium alloy is a locally compact film. However, because the porous substrate 11 is a porous structure, a titanium zirconium alloy film formed on the surface of the porous substrate 11 also becomes a porous continuous structure, and the pore diameter distribution of the titanium zirconium alloy film is slightly smaller than the micro-pore diameter of the surface of the porous substrate 11.

In this embodiment, as shown in FIG. 3 and FIG. 4, the vaporization core 10 further includes two electrodes 14. The two electrodes 14 are electrically connected to the power supply component 200 in the electronic vaporization device 300, and are configured to supply power to the heating layer 12 in the vaporization core 10, so that the heating layer 12 heats in the powered-on state, and then heats and vaporizes the aerosol-forming medium absorbed in the porous substrate 11 to generate an aerosol.

Specifically, both the two electrodes 14 are disposed on the surface of the side of the heating layer 12 far away from the porous substrate 11, and are respectively located on two sides of the protective layer 13, and the protective layer 13 covers a part of the heating layer 12 that is not covered by the two electrodes 14, so as to ensure that the heating layer 12 is completely covered by the protective layer 13 and the two electrodes 14, and cannot be in contact with air and oxidized in the vaporization process, thereby avoiding the problem that the heating layer 12 fails due to oxidation, thereby improving stability of the vaporization core 10, and prolonging the service life of the vaporization core 10.

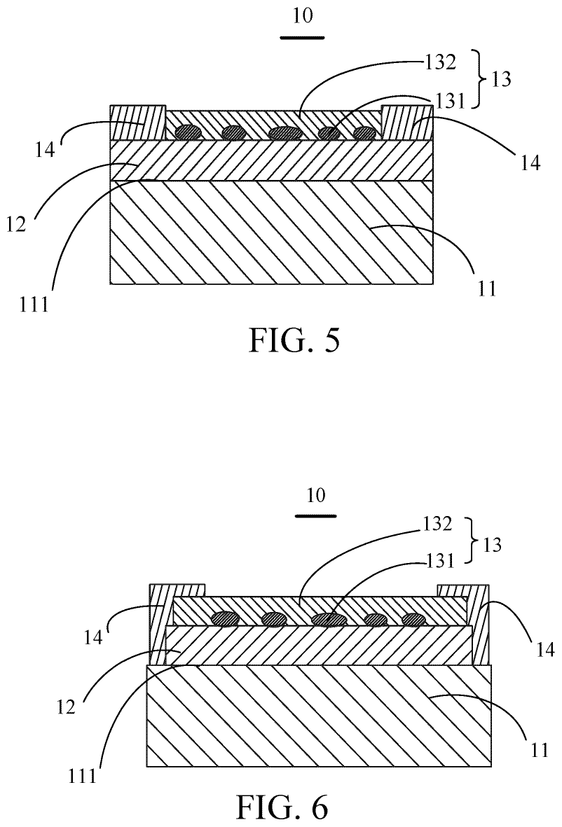

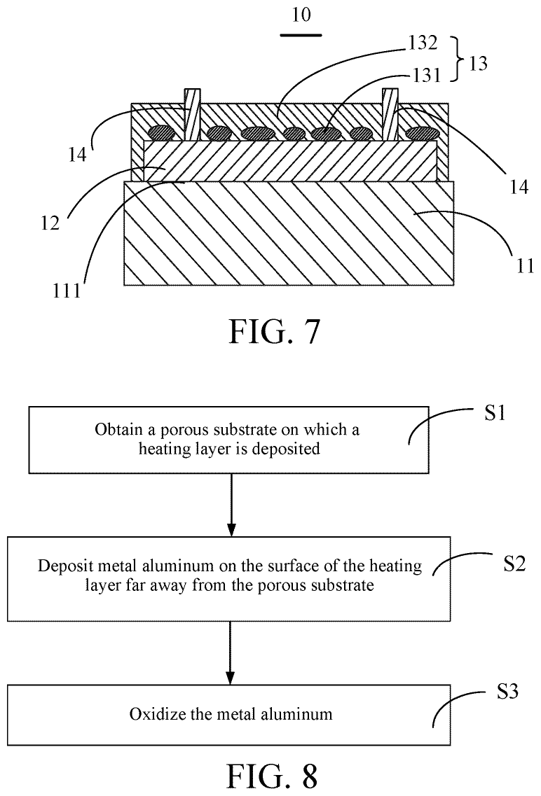

Referring to FIG. 5 to FIG. 7, FIG. 5 is a schematic structural diagram of a second embodiment of a vaporization core in FIG. 2. FIG. 6 is a schematic structural diagram of another implementation of the vaporization core in FIG. 5. FIG. 7 is a schematic structural diagram of still another implementation of the vaporization core in FIG. 5.

Referring to FIG. 5, in this embodiment, the structure of the protective layer 13 in the vaporization core 10 is different from the structure of the protective layer 13 in the first embodiment of the vaporization core 10, and other structures are the same as the structures in the first embodiment of the vaporization core 10. Details are not described herein again.

In this embodiment, the protective layer 13 includes metal aluminum and alumina, where the metal aluminum includes multiple aluminum particles 131. That is, the protective layer 13 includes multiple aluminum particles 131 and an alumina layer 132. Specifically, the multiple aluminum particles 131 may be multiple granular structures formed by agglomeration of the aluminum film layer 130 in FIG. 3 after the high-temperature annealing process, and the alumina layer 132 is located on the side of the multiple aluminum particles 131 far away from the porous substrate 11. The particle diameter range of the aluminum particle 131 is 100 nm to 3 μm. It may be understood that multiple aluminum particles 131 are formed by agglomeration of the aluminum film layer 130 in the annealing process, and the particle diameter of the aluminum particles 131 is greater than the thickness of the aluminum film layer 130. The multiple aluminum particles 131 are disposed at intervals, and alumina is filled between two adjacent aluminum particles 131. The alumina completely covers and wraps the surface of the multiple aluminum particles 131 not in contact with the heating layer 12, that is, the alumina layer 132 and the heating layer 12 jointly wrap the multiple aluminum particles 131. It may be understood that the material of the alumina layer 132 is an oxide, and an anti-oxidation capability of the alumina layer 132 is relatively strong. When the alumina layer 132 is in contact with air in the vaporization process, oxidation reaction does not easily occur, and performance of the alumina layer 132 does not change, thereby ensuring stability of the vaporization core 10. In addition, the alumina layer 132 has relatively high compactness, and has a relatively strong air barrier capability. The alumina layer 132 completely covers and wraps the multiple aluminum particles 131, and two adjacent aluminum particles 131 are filled with the alumina layer 132. Therefore, mutual contact between the multiple aluminum particles 131 can be prevented from affecting the compactness of the protective layer 13, affecting the air barrier capability of the protective layer 13, and weakening the protection effect of the protective layer 13 on the heating layer 12, thereby reducing the risk that the air contacts the heating layer 12 and causes oxidation and failure of the heating layer 12.

The aluminum particles 131 have better thermal conductivity, thereby improving electrical conductivity and thermal conductivity of the vaporization core 10, so that the alumina layer 132 can also play a role of vaporization, so that the heating layer 12 has stronger electrical conductivity and thermal conductivity in the vaporization process, and further, vaporization efficiency of the vaporization core 10 is higher. The multiple aluminum particles 131 and the alumina layer 132 are in contact with the heating layer 12, so that the heating layer 12 and the alumina layer 132 have better binding property. In addition, the multiple aluminum particles 131 are in a granular shape, and the coverage area of the alumina layer 132 on the heating layer 12 is increased, so that the protective layer 13 has a stronger protection effect on the heating layer 12.

In addition, the aluminum particles 131 are disposed on the surface of the heating layer 12 and are sintered with the heating layer 12, which is equivalent to that an interval projection is disposed on the surface of the heating layer 12, which increases the surface area of the heating layer 12 and the area of the alumina layer 132 near the surface of the heating layer 12. In addition, the multiple aluminum particles 131 protrude on the surface of the heating layer 12, which helps improve the vaporization effect, reduces plane stress, eliminates the possibility that the protective layer 13 breaks in the process of using the vaporization core 10, and effectively increases the service life of the vaporization core 10.

It may be understood that when the metal aluminum in FIG. 3 is not completely converted into the aluminum particles 131 in the high-temperature annealing process, the protective layer 13 includes an aluminum film layer 130 (continuous porous structure or mesh structure) and multiple aluminum particles 131.

Still referring to FIG. 5, in this embodiment, the structure of the electrode 14 is the same as the structure of the electrode 14 in the first embodiment of the vaporization core 10, and details are not described again.

In another implementation, as shown in FIG. 6, the protective layer 13 is disposed on the surface of the side of the heating layer 12 far away from the porous substrate 11, the two electrodes 14 are spaced on the surface of the side of the protective layer 13 far away from the porous substrate 11, and the two electrodes 14 cover a part of the heating layer 12 that is not covered by the protective layer 13. Both the two electrodes 14 are in contact with the protective layer 13, the heating layer 12, and the porous substrate 11, and both the two electrodes 14 are covered on the side of the protective layer 13 and the heating layer 12, so that when the electrodes 14 are disposed on two sides of the protective layer 13, there is a gap between the electrodes 14 and the protective layer 13, and contact between the air and the heating layer 12 cannot be completely separated, causing failure of the vaporization core 10.

In still another implementation, as shown in FIG. 7, the protective layer 13 may also completely cover the surface of the heating layer 12 far away from the porous substrate 11 and the side of the heating layer 12. That is, the protective layer 13 completely wraps the heating layer 12, to completely isolate the heating layer 12 from the air. Two mutually spaced through holes are provided on the protective layer 13 in a hole opening manner, and the two electrodes 14 are respectively electronically connected to the heating layer 12 through the two through holes in the protective layer 13, and the two electrodes 14 are electrically connected to the power supply component 200 when exposed on the surface of the side of the protective layer 13 far away from the porous substrate 11.

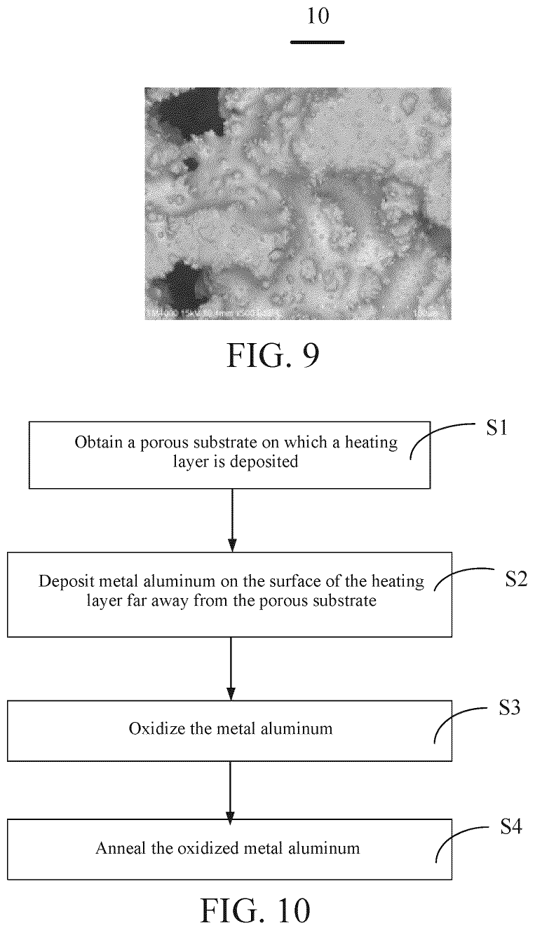

Referring to FIG. 8 and FIG. 9, FIG. 8 is a schematic flowchart of an embodiment of a vaporization core preparation method according to this application. FIG. 9 is a schematic diagram of a surface structure of step S3 in the vaporization core preparation method according to FIG. 8.

The preparation method for the vaporization core 10 in this application specifically includes the following steps:

S1: Obtain a porous substrate on which a heating layer is deposited.

Specifically, the porous substrate 11 is made of a material of a porous structure. In this embodiment, the material of the porous substrate 11 is a porous ceramic substrate. In another implementation, the porous substrate 11 may also be made of porous glass, porous plastic, porous metal, or the like.

The porous substrate 11 has a vaporization surface 111, and a heating layer 12 is deposited on the vaporization surface 111 of the porous substrate 11, so as to obtain the porous substrate 11 on which the heating layer 12 is deposited. A material that can be stably bound to the porous substrate 11 may be selected as the heating layer 12. For example, the heating layer 12 may be made of a material such as titanium, zirconium, titanium aluminum alloy, titanium zirconium alloy, titanium molybdenum alloy, titanium niobium alloy, iron aluminum alloy or tantalum aluminum alloy, or stainless steel. In this embodiment, the heating layer 12 is made of a titanium zirconium alloy material.

The heating layer 12 is prepared on the vaporization surface 111 of the porous substrate 11 by means of deposition, and may be prepared by using a process such as physical vapor deposition or chemical vapor deposition. For example, the heating layer 12 may be prepared by using a process such as sputtering, evaporation coating, or atomic layer deposition. In this embodiment, the heating layer 12 is formed on the vaporization surface 111 of the porous substrate 11 by using a sputtering process. Then, two electrodes 14 are disposed on two ends of the heating layer 12 on the surface of the side far away from the porous substrate 11, and the two electrodes 14 are spaced, so as to electrically connect the heating layer 12 and the power supply component 200 to provide energy for the prepared vaporization core 10.

S2: Deposit metal aluminum on the surface of the heating layer far away from the porous substrate.

Specifically, the step of depositing metal aluminum on the surface of the heating layer 12 far away from the porous substrate 11 is as follows:

S21: Deposit metal aluminum with a thickness of 100 nm to 1 μm on the surface of the heating layer 12 far away from the porous substrate 11.

The metal aluminum is prepared on the surface of the side of the heating layer 12 far away from the porous substrate 11 by means of deposition, and may be prepared by using a process such as physical vapor deposition or chemical vapor deposition. For example, the metal aluminum may be prepared by using a process such as sputtering, evaporation coating, or atomic layer deposition.

In this embodiment, the metal aluminum is prepared by using a sputtering process on the surface of the side of the heating layer 12 far away from the porous substrate 11. Before the sputtering process is performed on the heating layer 12, masks are disposed on the surfaces of the two electrodes 14 far away from the heating layer 12, so as to prevent sputtering of the metal aluminum onto the two electrodes 14. After sputtering is completed, the masks on the two electrodes 14 are removed. After the sputtering process, on the surface of the side of the heating layer 12 far away from the porous substrate 11, the metal aluminum and the two electrodes 14 completely cover the surface of the side of the heating layer 12 far away from the porous substrate 11, where the thickness of the sputtered metal aluminum is 100 nm to 1 μm.

S3: Oxidize the metal aluminum.

Specifically, the metal aluminum is oxidized for 50 min to 70 min at the air atmosphere and a temperature of 400° C. to 700° C.

The metal aluminum is oxidized in the air atmosphere and a high temperature environment to form an aluminum film layer 130 and an alumina layer 132, to form a protective layer 13 of the vaporization core 10 shown in FIG. 3. The alumina layer 132 is located on the side of the aluminum film layer 130 far away from the porous substrate 11, because the metal aluminum is oxidized in the direction from the side far away from the porous substrate 11 close to the porous substrate 11. The oxidation process is performed at a temperature of 400° C. to 700° C. In the whole oxidation process, the high temperature time is approximately 50 min to 70 min, and the heating time and the cooling time are approximately 50 min to 70 min. It may be understood that the thickness of the alumina layer 132 generated on the surface of the metal aluminum deposited on the surface of the heating layer 12 is related to the time of the oxidation process and the oxidation temperature. Specifically, the longer the oxidation time is, the higher the sintering temperature is, the more alumina is generated, and the greater the thickness of the alumina layer 132 is. After the oxidation process, the thickness of the alumina layer 132 is in a range of 100 nm to 600 nm. Preferably, the thickness of the alumina layer 132 is 100 nm to 300 nm. More preferably, when the thickness of the alumina layer 132 is 180 nm to 200 nm, the vaporization effect of the vaporization core 10 is stronger. In this embodiment, the thickness of the alumina layer 132 is 200 nm, so as to better protect the heating layer 12.

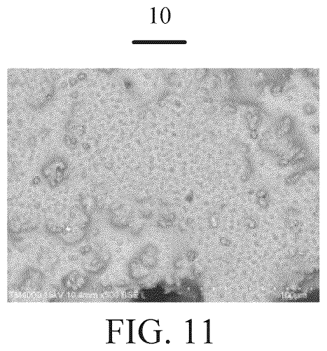

Referring to FIG. 10 and FIG. 11, FIG. 10 is a schematic flowchart of another embodiment of a vaporization core preparation method according to this application. FIG. 11 is a schematic diagram of a surface structure of step S4 in the vaporization core preparation method according to FIG. 10.

The preparation method for the vaporization core 10 provided in FIG. 10 is different from the preparation method for the vaporization core 10 provided in FIG. 8 in the following. After step S3, step S4 is further included.

S4: Anneal the oxidized metal aluminum.

Specifically, the oxidized metal aluminum is annealed for 6 h to 24 h at a vacuum degree of 0.01 pa to 100 pa and a temperature of 650° C. to 900° C.

After the metal aluminum deposited on the surface of the heating layer 12 is oxidized, the generated alumina layer 132 and the aluminum film layer 130 are annealed in a high vacuum environment, so that the heating layer 12 and the alumina layer 132 can be better bound. Specifically, the annealing process is performed at a vacuum degree of 0.01 pa to 100 pa, the annealing temperature is between 650° C. to 900° C., and the annealing time is 6 h to 24 h. After the aluminum film layer 130 and the alumina layer 132 are annealed, the aluminum film layer 130 agglomerates at a high temperature to form multiple aluminum particles 131 at intervals, and the particle diameter of the aluminum particles 131 is 100 nm to 3 μm, to form the protective layer 13 of the vaporization core 10 shown in FIG. 5. The alumina layer 132 completely covers the multiple aluminum particles 131, and the alumina layer 132 is filled between adjacent aluminum particles 131. Both the alumina layer 132 and the multiple aluminum particles 131 are in contact with the heating layer 12. After annealing, the alumina layer 132 has better bonding with the heating layer 12, and also improves electrical conductivity and heat conductivity of the heating layer 12, and improves heating efficiency of the vaporization core 10. The alumina layer 132 and the multiple aluminum particles 131 on the surface of the heating layer 12 constitute the protective layer 13. The protective layer 13 is configured to protect the heating layer 12, so as to prevent the heating layer 12 from being oxidized and failing due to contact with the air, thereby affecting stability and the service life of the vaporization core 10. In addition, the heating layer 12 has higher crystallinity after annealing, so that vaporization is more uniform, aerosols generated by vaporization increase, and vaporization efficiency of the vaporization core 10 is higher. Because the metal aluminum is converted into the alumina layer 132 and the aluminum particles 131 during oxidation and annealing, the bonding between the alumina layer 132 and the aluminum particles 131 is stronger. Compared with FIG. 9 and FIG. 11, after the annealing process, the crystallinity of the heating layer 12 is higher, the binding between the heating layer 12 and the protective layer 13 is better, vaporization of the vaporization core 10 is more uniform, more aerosols are generated, and vaporization efficiency is higher.

It may be understood that the two electrodes 14 may also be disposed after the metal aluminum is oxidized and annealed. For example, before the metal aluminum is deposited on the surface of the heating layer 12 far away from the porous substrate 11, two mutually spaced masks may be disposed at two ends on the surface of the heating layer 12 far away from the porous substrate 11. The metal aluminum is deposited at the part of the surface of the heating layer 12 that is not provided with a mask, and then the mask is removed. After the metal aluminum is oxidized and annealed, two electrodes 14 are disposed at the position at which the mask is removed, so as to be electrically connected to the heating layer 12 and the power supply component 200. Alternatively, the mask may not be disposed on the surface of the heating layer 12, and the metal aluminum is directly deposited on the surface of the heating layer 12 far away from the porous substrate 11, so that the metal aluminum completely covers the surface of the heating layer 12. After the metal aluminum is oxidized and annealed to form a stable protective layer 13, two spaced through-holes are disposed on the protective layer 13 in a hole opening manner, two electrodes 14 are electrically connected to the heating layer 12 through the through-holes in the protective layer 13, and both electrodes 14 are exposed on the surface of the side of the protective layer 13 far away from the porous substrate 11, so as to ensure a stable electrical connection to the power supply component 200.

In this embodiment, by using the foregoing preparation method for the vaporization core 10, the problem that the vaporization core 10 fails due to oxidation and agglomeration of precious metal particles can be effectively avoided, which helps to improve stability and increase the service life of the vaporization core 10.

Different from the prior art, this application discloses an electronic vaporization device, a vaporizer, a vaporization core, and a preparation method therefor. The vaporization core includes a porous substrate, a heating layer, and a protective layer; the porous substrate has a vaporization surface, the heating layer is disposed on the vaporization surface of the porous substrate, the protective layer is disposed on the surface of the heating layer far away from the porous substrate, the protective layer includes metal aluminum and alumina, and the alumina at least partially covers the surface of the metal aluminum to form an alumina layer. The protective layer formed of metal aluminum and alumina is disposed on the surface of the heating layer far away from the porous substrate, so that failure of the heating layer on the vaporization core due to oxidization when in direct contact with air can be avoided in the vaporization process, which affects stability and the service life of the vaporization core. In addition, the problem of failure of the vaporization core caused by over-burning and agglomeration of precious metal particles when the aerosol-forming medium in the vaporization core is insufficient when the precious metal material is used as the protective layer of the heating layer in the prior art is solved, and the production costs of the vaporization core are reduced.

The foregoing descriptions are merely embodiments of this application, and the patent scope of this application is not limited thereto. All equivalent structure or process changes made according to the content of this specification and accompanying drawings in this application or by directly or indirectly applying this application in other related technical fields shall similarly fall within the patent protection scope of this application.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and

C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A vaporization core, comprising:
a porous substrate having a vaporization surface;
a heating layer disposed on the vaporization surface of the porous substrate; and
a protective layer disposed on a surface of the heating layer far away from the porous substrate,
wherein the protective layer comprises metal aluminum and alumina, and the alumina at least partially covers a surface of the metal aluminum to form an alumina layer.

2. The vaporization core of claim 1, wherein the metal aluminum comprises an aluminum film layer and/or an aluminum particle form.

3. The vaporization core of claim 2, wherein the alumina is filled between adjacent aluminum particles, and multiple aluminum particles and the alumina are in contact with the heating layer.

4. The vaporization core of claim 2, wherein the alumina completely covers surfaces of multiple aluminum particles not in contact with the heating layer.

5. The vaporization core of claim 1, further comprising:
two electrodes disposed on a surface of the heating layer far from the porous substrate,
wherein the protective layer and the two electrodes jointly cover the heating layer.

6. The vaporization core of claim 2, wherein a thickness of the alumina layer is 100 nm to 600 nm, and/or
wherein a particle diameter of the aluminum particle is 100 nm to 3 μm, and/or
wherein a thickness of the aluminum film layer is 100 nm to 1 μm.

7. A vaporizer, comprising:
a liquid storage cavity configured to store an aerosol-forming medium; and
the vaporization core of claim 1,
wherein the vaporization core is configured to heat and vaporize the aerosol-forming medium.

8. An electronic vaporization device, comprising:
a power supply component; and
the vaporizer of claim 7,
wherein the power supply component is configured to provide energy for the vaporizer.

9. A vaporization core preparation method, comprising:
obtaining a porous substrate on which a heating layer is deposited;
depositing metal aluminum on a surface of the heating layer far away from the porous substrate; and
oxidizing the metal aluminum to form oxidized metal aluminum.

10. The vaporization core preparation method of claim 9, wherein depositing metal aluminum on the surface of the heating layer far away from the porous substrate comprises:
depositing metal aluminum with a thickness of 100 nm to 1 μm on the surface of the heating layer far away from the porous substrate.

11. The vaporization core preparation method of claim 9, wherein oxidizing the metal aluminum comprises:
oxidizing the metal aluminum for 50 minutes to 70 minutes at an air atmosphere and a temperature of 400° C. to 700° C.

12. The vaporization core preparation method of claim 9, further comprising:
annealing the oxidized metal aluminum.

13. The vaporization core preparation method of claim 12, wherein annealing the oxidized metal aluminum comprises:
annealing the oxidized metal aluminum for 6 hours to 24 hours at a vacuum degree of 0.01 Pa to 100 Pa and a temperature of 650° C. to 900° C.
